(19) United States
(12) Patent Application Publication
(10) Pub. No.: US 2026/0206365 A1
(43) Pub. Date: Jul. 16, 2026

(54) TUNNEL JUNCTION BASED RGB DIE AND DRIVING SCHEME

(71) Applicant: Lumileds LLC, San Jose, CA (US)

(72) Inventor: Toni Lopez, Vaals (NL)

(73) Assignee: Lumileds LLC, San Jose, CA (US)

(21) Appl. No.: 19/136,608

(22) PCT Filed: Dec. 12, 2023
(86) PCT No.: PCT/US2023/083520

§ 371 Date: Jun. 6, 2025

Related U.S. Application Data
(60) Provisional application No. 63/431,943, filed on Dec. 12, 2022.

(51) Int. Cl. H10H 20/813; H10H 20/01; H10H 20/812; H10H 20/825; H10H 20/831; H10H 20/841

(52) U.S. Cl. CPC H10H 20/8131; H10H 20/01335; H10H 20/032; H10H 20/034; H10H 20/812; H10H 20/825; H10H 20/8312; H10H 20/841

(57) ABSTRACT

Provided is a tunnel junction based RGB die and driving scheme. The μLED die of one or more embodiments advantageously requires three plated metals and one common cathode per red-green-blue (RGB) pixel group. Additionally, the μLED die of one or more embodiments allows for better control of emission color than in known RGB technologies. A red pixel, a green pixel, and a blue pixel are grown sequentially on the same epitaxial wafer. A driving scheme is provided that includes a single current source per RGB pixel. This is enabled by way of using PWM switches and a proper selection of the active region area per active region color.

### TECHNICAL FIELD

Embodiments of the disclosure generally relate to arrays of light emitting diode (LED) devices and methods of manufacturing the same. More particularly, embodiments are directed to monolithic arrays of red, green, blue (RGB) LED pixels on an epi wafer and driving schemes.

### BACKGROUND

A light emitting diode (LED) is a semiconductor light source that emits visible light when current flows through it. LEDs combine a P-type semiconductor with an N-type semiconductor. LEDs commonly use a III-V group compound semiconductor. A III-V group compound semiconductor provides stable operation at a higher temperature than devices that use other semiconductors. The III-V group compound is typically formed on a substrate formed of sapphire aluminum oxide (Al₂O₃) or silicon carbide (SiC).

Various emerging display applications, including wearable devices, head-mounted, and large-area displays require miniaturized chips composed of arrays of microLEDs (μLEDs or uLEDs) with a high density having a lateral dimension down to less than 100 μm×100 μm. MicroLEDs (uLEDs) typically have dimensions of about 50 μm in diameter or width and smaller that are used to in the manufacture of color displays by aligning in close proximity microLEDs comprising red, blue and green wavelengths. Generally, two approaches have been utilized to assemble displays constructed from individual microLED dies. The first is a pick-and-place approach includes: picking up, aligning, and then attaching each individual blue, green and red wavelength microLED onto a backplane, followed by electrically connecting the backplane to a driver integrated circuit. Due to the small size of each microLED, this assembly sequence is slow and subject to manufacturing errors. Furthermore, as the die size decreases to satisfy increasing resolution requirements of displays, larger and larger numbers of die must be transferred at each pick and place operation to populate a display of required dimensions. A second approach is bonding a group of LEDs, e.g., a monolithic die or array or matrix, to a backplane, which eliminates the handling of individual LEDs associated with pick-and-place.

Visualization systems, such as virtual reality systems and augmented reality systems, are becoming increasingly more common in the fields such as entertainment, education, medicine, and business. There is ongoing effort to improve visualization systems, such as virtual reality systems and augmented reality systems.

Inorganic light emitting diodes (i-LEDs) have been widely used to create different types of displays, LED matrices, and light engines, including automotive adaptive headlights, augmented-, virtual-, mix-reality (AR/VR/MR) headsets, smart glasses, and displays for mobile phones, smart watches, monitors, and televisions. The individual LED pixels in these architectures may have an area of a few square millimeters down to a few square micrometers, depending upon the matrix or display size and its pixel per inch requirements. One common approach is to create a monolithic array of LED pixels on an EPI wafer and later transfer and hybridize these LED arrays to a backplane to control individual pixels.

Micro-LEDs (uLEDs) may be small size LEDs (typically ~50 μm in diameter or smaller) that can be used to produce very high-resolution color displays when μLEDs of red, green, and blue wavelengths may be aligned in close proximity. Manufacture of an μLED display typically involves picking singulated μLEDs from separate blue, green and red WL wafers and aligning them in alternating close proximity on the display.

Accordingly, there is a need for improved μLED devices and for improved driving schemes ultimately impacting performance and manufacturing feasibility.

### SUMMARY

Embodiments of the disclosure are directed to light emitting diode (LED) arrays and methods for manufacturing LED. In one or more embodiments, a light emitting diode (LED) comprises a microLED die comprising an RGB pixel; and a driving scheme comprising a current source and three PWM switches per RGB pixel.

Further embodiments of the disclosure are directed to methods of manufacturing light emitting diode (LED) device. In one or more embodiments, a method of manufacturing an LED device comprises: depositing a plurality of semiconductor layers including an N-type layer, an active region, and a P-type layer on a substrate; etching a portion of the semiconductor layers to form trenches and a first mesa, a second mesa, and a third mesa, wherein: the first mesa defines a red pixel, the first mesa comprising semiconductor layers, three active regions, two tunnel junctions, a transparent conductive oxide layer, and a first plated metal plug; the second mesa adjacent the first mesa, the second mesa defines a green pixel and comprising semiconductor layers, two active regions, two tunnel junctions, and a second plated metal plug; the third mesa adjacent the second mesa, the third mesa defines a blue pixel and comprising semiconductor layers, one active region, one tunnel junction, and a third plated plug; depositing a first dielectric material in a portion of the trenches; depositing a plated metal layer in the trenches; and forming a driving scheme.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a process flow diagram of a method of manufacturing an LED array according to one or more embodiments;

FIG. 1B illustrates a process flow diagram of a method of manufacturing an LED array according to one or more embodiments;

FIG. 2 illustrates a cross-section schematic of an epitaxy configuration with driving scheme according to one or more embodiments;

FIG. 3 illustrates a schematic of an electronics driving scheme that could be used with the epitaxy configuration of one of more embodiments;

FIG. 4 illustrates a schematic of an electronics driving scheme that could be used with the epitaxy configuration of one of more embodiments;

FIG. 5A illustrates a schematic of an electronics driving scheme that could be used with the epitaxy configuration of one of more embodiments;

FIG. 5B illustrates a schematic of an electronics driving scheme that could be used with the epitaxy configuration of one of more embodiments;

FIG. 6 illustrates a schematic of an electronics driving scheme that could be used with the epitaxy configuration of one of more embodiments; and

FIG. 7 illustrates a block diagram of an example of a visualization system using the μLED array of one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to a micro-LED (uLED) means a light emitting diode having one or more characteristic dimensions (e.g., height, width, depth, thickness, etc. dimensions) of less than 100 micrometers. In one or embodiments, one or more dimensions of height, width, depth, thickness have values in a range of 2 to 25 micrometers.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of micro light emitting diode (μLED) displays and of multi-wavelength light emitters with large bandwidth for free-space visible light communications. Epitaxial tunnel junctions may be used to combine multiple emission wavelengths within a single LED device.

The present disclosure generally relates to the manufacture of LEDs and arrays for augmented reality (AR) lighting.

Manufacturing μLEDs could be simplified if two or more active regions emitting different wavelengths may be integrated within a single wafer. Such an approach may be possible within the AlInGaN materials system since it has been demonstrated that blue, green, and red LEDs can be all made in this system. However, use of a multi-color chip in a μLED display requires not only stacking multiple layers able to emit at different wavelengths within a single epitaxial growth run, but also requires an ability to change respective emission intensity ratios between the emitters of different wavelengths.

In one or more embodiments, a three-color (red-green-blue) indium gallium nitride (InGaN) based epitaxial die is made with a stack of multiple quantum wells and tunnel junctions. In one or more embodiments, the complexity of each individual RGB pixel group is reduced in terms of interconnect electrodes, color control, and driving schemes ultimately improving performance and manufacturing feasibility.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

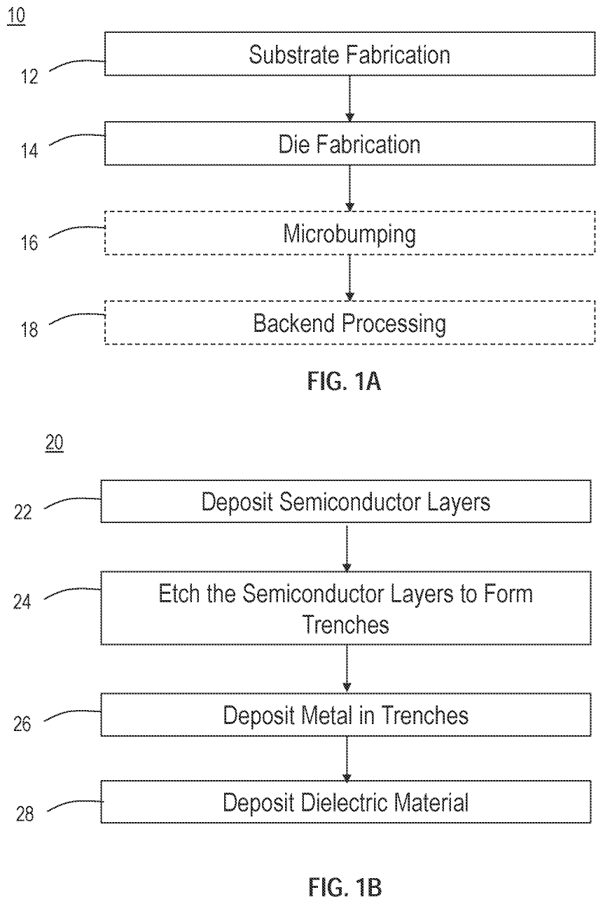

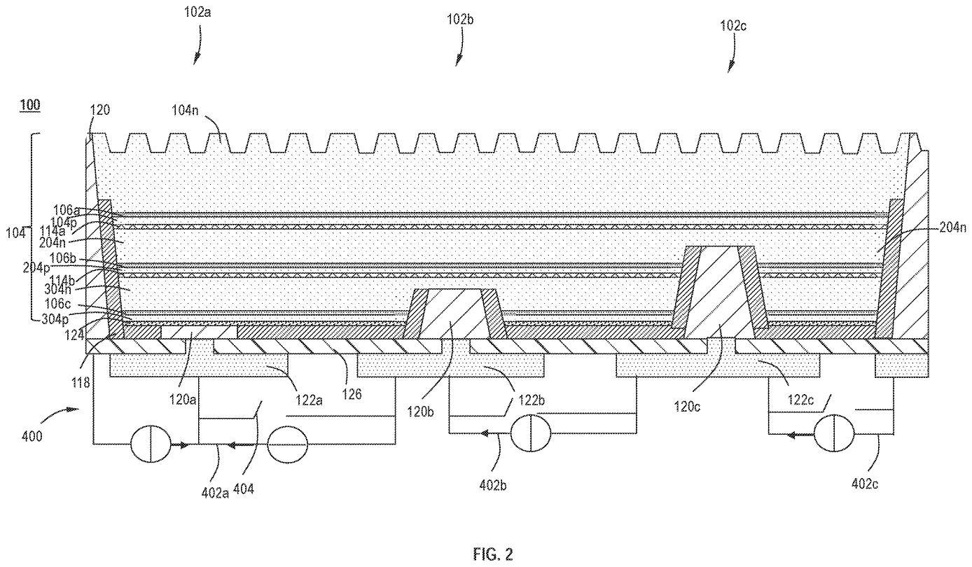

One or more embodiments of the disclosure are described with reference to the Figures. FIG. 1A illustrates a process flow diagram for a method 50 on manufacturing an LED device according to one or more embodiments. FIG. 1A illustrates a process flow diagram for a method 50 on manufacturing an LED device according to one or more embodiments. FIG. 2 is a cross-section view of a μLED 100 according to one or more embodiments.

The μLED array of one or more embodiments advantageously requires three plated metals and one common cathode per red-green-blue (RGB) pixel group. Additionally, the μLED array of one or more embodiments allows for better control of emission color than in known RGB technologies. Without intending to be bound by theory, it is thought that the μLED arrays of one or more embodiments are capable of lower display power consumption than published RGB technologies.

In one or more embodiments, a red pixel, a green pixel, and a blue pixel are grown sequentially on the same epitaxial wafer. Each pixel contains at least one active region and at least one tunnel junction Each active region emits light of different wavelength than the other active region(s).

In one or more embodiments, the epitaxy includes at least one tunnel junction to avoid the need for contacts to etched p-GaN layers. The wafer is etched into multi-level mesas creating connected to multi-level plated metals. All of the isolated pixels share a common cathode.

With reference to FIG. 1A, the method 10 comprises at operation 12 fabrication of a substrate. Substrate fabrication can include depositing a plurality of semiconductor layers including, but not limited to an N-type layer, an active region, and a P-type layer on a substrate. Once the semiconductor layers are deposited on the substrate, a portion of the semiconductor layers are etched to form trenches and a plurality of spaces mesas. At operation 14, a die is fabricated. Die fabrication includes depositing a (first) dielectric material to insulate sidewalls of the epitaxial layers (e.g., N-type layer, active region, and P-type layer), which is followed by deposition of an electrode metal in the trenches, e.g., spaces between each of the plurality of spaced mesas. In some embodiments, the die fabrication further includes depositing a P-contact layer and a hard mask, forming a current spreading film, plating a p-metal material plug, followed by under bump metallization (UBM). At operation 16, optional microbumping may occur on a complementary metal oxide semiconductor (CMOS) backplane. At operation 18, optionally, backend processing occurs such that the die is connected to the CMOS backplane, underfill is provided, laser lift off occurs, followed by optional phosphor integration.

With reference to FIG. 1B, in one embodiment, the method 20 comprises at 22 depositing a plurality of semiconductor layers including an N-type layer, an active region, and a P-type layer on a substrate. At 24, the method further comprises etching a portion of the semiconductor layers to form trenches and a plurality of spaced mesas defining pixels, each of the plurality of spaced mesas comprising the semiconductor layers and each of the spaced mesas having a height less than or equal to their width. At 26, the method comprises depositing a dielectric material which insulates sidewalls of the P-type layer and the active region from the metal. At 28, the method comprises depositing an electrode metal in a space between each of the plurality of spaced mesas, the metal providing optical isolation between each of the spaced mesas, and electrically contacting the N-type layer of each of the spaced mesas along sidewalls of the N-type layers. In one or more embodiments, each of the plurality of spaced mesas comprising a conductive p-contact layer extending across a portion of each of the plurality of mesas and including an edge, and the space between each of the plurality of spaced mesas results in a pixel pitch in a range of from 1 μm to 100 μm and dark space gap between adjacent edges of the p-contact layer of less than 20% of the pixel pitch. In some embodiments, the pixel pitches are in a range of from 5 μm to 100 μm, 10 μm to 100 μm or 15 μm to 100 μm. In other embodiments, the dark space gap is in a range of from 10 μm to 0.5 μm, or in a range of from 10 μm to 4 μm, for example, in a range of 8 μm to 4 μm. As used herein, according to one or more embodiments, the term “dark space gap” refers to the space between adjacent edges of the p-contact layer where no light is reflected.

In some embodiments, the method comprises forming an array of spaced mesas. In some embodiments, the metal comprises a reflective metal. In some embodiments, the dark space gap is in a range of from to 10 μm to 0.5 μm or in a range of from 10 μm to 4 μm. In some embodiments, the plurality of spaced mesas is arranged into pixels, and the pixel pitch in a range of from 5 μm to 100 μm or from 30 μm to 50 μm. In some embodiments, the semiconductor layers 104 have a thickness in a range of from 2 μm to 10 μm.

FIG. 2 is a cross-sectional view of a tunnel junction based RGB die 100 with isolated active regions. The RGB die 100 has three pixel stacks 102a, 102b, 102c of varying heights. Each pixel stack 102a, 102b, 102c includes semiconductor layers 104, active regions 106, and tunnel junctions 114 deposited on a substrate (not illustrated) during a step in the manufacture of an LED device according to one or more embodiments. With reference to FIG. 2, each pixel stack 102a, 102b, and 102c comprises at least one active region 106, which may also be known as a blue active region because of its ability to emit blue light. Semiconductor layers 104 are grown on a substrate. The semiconductor layers 104, according to one or more embodiments, comprise epitaxial layers, III-nitride layers, or epitaxial III-nitride layers.

In one or more embodiments, each pixel stack 102a, 102b, 102c, has a thickness in a range of from 1 μm to 10 μm.

The substrate may be any substrate known to one of skill in the art. In one or more embodiments, the substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the epitaxial layer(s). Thus, in some embodiments, the substrate is not patterned and can be considered to be flat or substantially flat. In other embodiments, the substrate is patterned, e.g., patterned sapphire substrate (PSS).

In one or more embodiments, the semiconductor layers 104 comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers 104 comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. In one or more specific embodiments, the semiconductor layers 104 comprises a p-type layer 104p, at least one an active region 106, and an n-type layer 104n. In one or more embodiments, the semiconductor layers 104 comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers 104 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. In one or more specific embodiments, the semiconductor layers 104 comprises a p-type layer 104p, at least one active region 106, and an n-type layer 104n.

In one or more embodiments, the substrate is placed in a metalorganic vapor-phase epitaxy (MOVPE) reactor for epitaxy of LED device layers to grow the semiconductor layers.

In one or more embodiments, the semiconductor layers 104 comprise a stack of undoped III-nitride material and doped III-nitride material. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In specific embodiments, the semiconductor layers 104 comprise an n-type layer 104n, an active region 106 and a p-type layer 104p.

In one or more embodiments, the semiconductor layers 104 have a combined thickness in a range of from about 2 μm to about 10 μm, including a range of from about 2 μm to about 9 μm, 2 μm to about 8 μm, 2 μm to about 7 μm, 2 μm to about 6 μm, 2 μm to about 5 μm, 2 μm to about 4 μm, 2 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

In one or more embodiments, each pixel stack 102a, 102b, 102c, includes a first active region 106a, or a blue active region, formed between the first n-type layer 104n and the first p-type layer 104p. The first active region 106a may comprise any appropriate materials known to one of skill in the art. In one or more embodiments, the active region 106 is comprised of a III-nitride material multiple quantum wells (MQW), and a III-nitride electron blocking layer.

In one or more embodiments, the first pixel stack 102a includes a second active region 106b and a third active region 106c. In some embodiments, the second active region 106b is also known as a green active region because it emits green light. In one or more embodiments, the third active region 106c is known as a red active region because it emits red light. In one or more embodiments, because the first pixel stack 102a includes a first active region 106a, a second active region 106b, and a third active region 106c, the first pixel stack 102a is a red pixel.

In one or more embodiments, the first pixel stack 102a includes a first tunnel junction 114a, and a second tunnel junction 114b. A tunnel junction is a structure that allows electrons to tunnel from the valence band of a p-type layer to the conduction band of an n-type layer in reverse bias. The location where a p-type layer and an n-type layer abut each other is called a p/n junction. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p/n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling.

The first tunnel junction 114a is located between the first p-type layer 104p and the second n-type layer 204n. The second tunnel junction 114b is located between the second p-type layer 204p and the third n-type layer 304n.

In one or more embodiments, the second pixel stack 102b includes a first active region 106a, or a blue active region, formed between the first n-type layer 104n and the first p-type layer 104p. The first active region 106a may comprise any appropriate materials known to one of skill in the art. In one or more embodiments, the active region 106 is comprised of a III-nitride material multiple quantum wells (MQW), and a III-nitride electron blocking layer. In one or more embodiments, the second pixel stack 102b includes a second active region 106b. In some embodiments, the second active region 106b is also known as a green active region because it emits green light. In one or more embodiments, because the second pixel stack 102b includes a first active region 106 and a second active region 106b, the second pixel stack 102b is a green pixel. Without intending to be bound be theory, it is thought that because there is no third active region 106c, there is no red active region to absorb green photons. Thus, the second pixel stack 102b is a green pixel.

In one or more embodiments, the third pixel stack 102c includes a first tunnel junction 114a. The first tunnel junction 114a is located between the first active region 106 and the first p-type layer 104p. Without intending to be bound be theory, it is thought that because there is no third active region 106c and no second active region 106b, there is no red active region to absorb green photons and there is no green active region to absorb blue photons. Thus, the third pixel stack 102c is a blue pixel.

In one or more embodiments, the third pixel stack 102c includes a first tunnel junction 114a. The first tunnel junction 114a is located between the first p-type layer 104p and the second n-type layer 204n.

Accordingly, in one or more embodiments, the LED 100 is a red-green-blue (RGB) LED.

In one or more embodiments, the first pixel stack 102a includes a current spreading layer 124 on the third n-type layer 304n before the third p-type layer 304p. In one or more embodiments, the current spreading layer 124 comprises a transparent material. The current spreading layer 124 is separate from a reflecting layer. In this way, the function of current spreading is achieved in a different layer from the function of reflection. In one or more embodiments, the current spreading layer 124 comprises indium tin oxide (ITO) or other suitable conducting, transparent materials, e.g., transparent conductive oxides (TCO), such as indium zinc oxide (IZO), the current spreading layer 124 having a thickness in a range of from 5 nm to 100 nm.

In the first pixel stack 102a, in one or more embodiments, a first dielectric layer 118 is deposited on the third p-type layer 304p. In the second pixel stack 102b, in one or more embodiments, the first dielectric layer 118 is deposited on the third n-type layer 305n. In the third pixel stack 102c, in one or more embodiments, the first dielectric layer 118 is deposited on the second n-type layer 204n.

In one or more embodiments, the first dielectric layer 118 may be deposited by any appropriate technique known to the skilled artisan. In one or more embodiments, the first dielectric layer 118 is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a metal, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition (CVD)” refers to a process in which films of materials are deposited from the vapor phase by decomposition of chemicals on a substrate surface. In CVD, a substrate surface is exposed to precursors and/or co-reagents simultaneous or substantially simultaneously. As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. A PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step maybe conducted between the delivery of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, the first dielectric layer 118 may be fabricated using materials and patterning techniques which are known in the art. In some embodiments, the first dielectric layer 118 comprises a dielectric material. Suitable dielectric materials include, but are not limited to, silicon oxide (SiO), silicon nitride (SiN), silicon carbide (SiC), aluminum oxide (AlOx), aluminum nitride (AlN) and combinations thereof. The skilled artisan will recognize that the use of formulas like SiO, to represent silicon oxide, does not imply any particular stoichiometric relationship between the elements. The formula merely identifies the primary elements of the film.

As used herein, the term “dielectric” refers to an electrical insulator material that can be polarized by an applied electric field. In one or more embodiments, the first dielectric layer 118 includes, but is not limited to, oxides, e.g., silicon oxide (SiO₂), aluminum oxide (Al₂O₃), nitrides, e.g., silicon nitride (Si₃N₄). In other embodiments, the first dielectric layer 118 comprises silicon oxide (SiO₂). In some embodiments, the first dielectric layer 118 composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In some embodiments, the first dielectric layer 118 may be a distributed Bragg reflector (DBR). As used herein, a “distributed Bragg reflector” refers to a structure (e.g., a mirror) formed from a multilayer stack of alternating thin film materials with varying refractive index, for example high-index and low-index films.

In one or more embodiments, the first dielectric layer 118 has a thickness in a range of from about 200 nm to about 1 μm, for example, about 300 nm to about 1 μm, about 400 nm to about 1 μm, about 500 nm to about 1 μm, about 600 nm to about 1 μm, about 700 nm to about 1 μm, about 800 nm to about 1 μm, about 500 nm to about 1 μm, about 200 nm to about 900 nm, 300 nm to about 900 nm, about 400 nm to about 900 nm, about 500 nm to about 900 nm, about 600 nm to about 900 nm, about 700 nm to about 900 nm, about 800 nm to about 900 nm, about 200 nm to about 800 nm, 300 nm to about 800 nm, about 400 nm to about 800 nm, about 500 nm to about 800 nm, about 600 nm to about 800 nm, about 700 nm to about 800 nm, about 200 nm to about 700 nm, about 300 nm to about 700 nm, about 400 nm to about 700 nm, about 500 nm to about 700 nm, about 600 nm to about 700 nm, about 200 nm to about 600 nm, about 300 nm to about 600 nm, about 400 nm to about 600 nm, about 500 nm to about 600 nm, about 200 nm to about 500 nm, about 300 nm to about 500 nm, about 300 nm to about 400 nm, about 200 nm to about 400 nm, or about 300 nm to about 400 nm.

Referring to FIG. 2, in one or more embodiments, the first dielectric layer 118 of the first pixel stack 102a extends to the third active region 106c. In one or more embodiments, the inner first dielectric layer 118 of the second pixel stack 102b extends to the second active region 106b. In one or more embodiments, the inner first dielectric layer 118 of the third pixel stack 102c extends to the first active region 106.

In one or more embodiments, the first dielectric layer 118 is patterned according to any appropriate patterning technique known to one of skill in the art. In one or more embodiments, the first dielectric layer 118 is patterned by etching. According to one or more embodiments, conventional masking, wet etching and/or dry etching processes can be used to pattern the first dielectric layer 118.

In other embodiments, a pattern is transferred to the first dielectric layer 118 using nanoimprint lithography. In one or more embodiments, the substrate is etched in a reactive ion etching (RIE) tool using conditions that etch the first dielectric layer efficiently but etch the third p-type layer 304p or the third n-type layer 304n or the second n-type layer 204n very slowly or not at all. In other words, the etching is selective to the first dielectric layer 118 over the third p-type layer 304p or the third n-type layer 304n or the second n-type layer 204n. In a patterning step, it is understood that masking techniques may be used to achieve a desired pattern.

FIG. 2 is a cross-sectional view of the stack after a step in the manufacture of a LED device 100 according to one or more embodiments. With reference to FIG. 2, the first dielectric layer 118 is patterned to form an opening (not illustrated) between the first dielectric layer 118, exposing a top surface of the semiconductor layers 104. In the opening formed on each pixel stack 120a, 102b, and 102c is filled with a plated metal 120a, 120b, and 120c for both side n-contact (e.g., common cathode) and individual plated metals is formed.

As illustrated in FIG. 2, in one or more embodiments, each of the plated metals 120a, 120b, 120c has a different thickness. In one or more embodiments, the first plated metal 120a has a first thickness, T1, the second plated metal 120b has a second thickness, T2, and the third plated metal has a third thickness, T3. In some embodiments, the second plated metal 120b has a second thickness, T2, that is greater than the first thickness, T1 of the first plated metal 120a. In one or more embodiments, the third plated metal 120c has a third thickness, T3, that is greater than the second thickness, T2 of the second plated metal 120b.

In one or more embodiments, the plated metal 120a, 120b, and 120c may comprise any suitable material known to the skilled artisan. In one or more embodiments, the plated metal 120a, 120b, and 120c may comprise one or more of aluminum (Al), silver (Ag), gold (Au), platinum (Pt), and palladium (Pd). In specific embodiments, the plated metal 120a, 120b, and 120c comprises silver (Ag). In some embodiments, additional metals may be added in small quantities to the plated metal 120a, 120b, and 120c as adhesion promoters. Such adhesion promoters, include, but are not limited to, one or more of nickel (Ni), titanium (Ti), and chromium (Cr).

With reference to FIG. 2, an electrode metal, e.g., to yield the plated metal 120a, 120b, and 120c is deposited on the substrate, including on top of the mesas or pixel stacks 102a, 102b, 102c in the opening. The electrode metal can comprise any appropriate material known to the skilled artisan. In one or more embodiments, the electrode metal comprises copper and the electrode metal material is deposited by electrochemical deposition (ECD) of the copper.

With reference to FIG. 2, the electrode metal is planarized, etched, or polished to yield the plated metal 120a, 120b, and 120c. As used herein, the term “planarized” refers to a process of smoothing surfaces and includes, but is not limited to, chemical mechanical polishing/planarization (CMP), etching, and the like.

In one or more embodiments, a second dielectric layer 126 is deposited along each of the spaced mesas 120a, 120b, 120c. In one or more embodiments, the second dielectric layer 126 may be deposited by any appropriate technique known to the skilled artisan. In one or more embodiments, the second dielectric layer 126 is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the second dielectric layer 126 may be fabricated using materials and patterning techniques which are known in the art. In some embodiments, the second dielectric layer 126 comprises a dielectric material. Suitable dielectric materials include, but are not limited to, silicon oxide (SiO), silicon nitride (SiN), silicon carbide (SiC), aluminum oxide (AlOₓ), aluminum nitride (AlN) and combinations thereof. The skilled artisan will recognize that the use of formulas like SiO, to represent silicon oxide, does not imply any particular stoichiometric relationship between the elements. The formula merely identifies the primary elements of the film.

In one or more embodiments, the second dielectric layer 126 includes, but is not limited to, oxides, e.g., silicon oxide (SiO₂), aluminum oxide (Al₂O₃), nitrides, e.g., silicon nitride (Si₃N₄). In other embodiments, the second dielectric layer 126 comprises silicon oxide (SiO₂). In some embodiments, the second dielectric layer 126 composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In some embodiments, the second dielectric layer 126 may be a distributed Bragg reflector (DBR). As used herein, a “distributed Bragg reflector” refers to a structure (e.g., a mirror) formed from a multilayer stack of alternating thin film materials with varying refractive index, for example high-index and low-index films.

In one or more embodiments, the second dielectric layer 126 has a thickness in a range of from about 200 nm to about 1 μm, for example, about 300 nm to about 1 μm, about 400 nm to about 1 μm, about 500 nm to about 1 μm, about 600 nm to about 1 μm, about 700 nm to about 1 μm, about 800 nm to about 1 μm, about 500 nm to about 1 μm, about 200 nm to about 900 nm, 300 nm to about 900 nm, about 400 nm to about 900 nm, about 500 nm to about 900 nm, about 600 nm to about 900 nm, about 700 nm to about 900 nm, about 800 nm to about 900 nm, about 200 nm to about 800 nm, 300 nm to about 800 nm, about 400 nm to about 800 nm, about 500 nm to about 800 nm, about 600 nm to about 800 nm, about 700 nm to about 800 nm, about 200 nm to about 700 nm, about 300 nm to about 700 nm, about 400 nm to about 700 nm, about 500 nm to about 700 nm, about 600 nm to about 700 nm, about 200 nm to about 600 nm, about 300 nm to about 600 nm, about 400 nm to about 600 nm, about 500 nm to about 600 nm, about 200 nm to about 500 nm, about 300 nm to about 500 nm, about 300 nm to about 400 nm, about 200 nm to about 400 nm, or about 300 nm to about 400 nm.

In one or more embodiments, the second dielectric layer 126 is patterned according to any appropriate patterning technique known to one of skill in the art. In one or more embodiments, the second dielectric layer 126 is patterned by etching. According to one or more embodiments, conventional masking, wet etching and/or dry etching processes can be used to pattern the second dielectric layer 126.

In other embodiments, a pattern is transferred to the second dielectric layer 126 using nanoimprint lithography. In one or more embodiments, the substrate is etched in a reactive ion etching (RIE) tool using conditions that etch the second dielectric layer 126 efficiently but etch the plated metal 120a, 120b, 120c. In other words, the etching is selective to the second dielectric layer 126 over the plated metal 120a, 120b, 120c. In a patterning step, it is understood that masking techniques may be used to achieve a desired pattern.

With reference to FIG. 2, under bump metallization (UBM) material forms an under-bump metallization (UBM) layer 122a, which is deposited in the openings (not illustrated) of the second dielectric layer 126. As used herein, “under bump metallization (UBM)” refers to the metal layer which is required for connecting a die to a substrate with solder bumps for flip-chip packages. In one or more embodiments, the UBM layer 122a, 122b, 122c may be a patterned, thin-film stack of material that provides an electrical connection from the die to a solder bump, provides a barrier function to limit unwanted diffusion from the bump to the die, and provides a mechanical interconnection of the solder bump to the die through adhesion to the die passivation and attachment to a solder bump pad. The UBM layer 122a, 122b, 122c may comprise any suitable metal known to the skilled artisan. In one or more embodiments, the UBM layer 122a, 122b, 122c may comprise gold (Au).

In one or more embodiments, under bump metallization (UBM) may be achieved by any technique known to one of skill in the art including, but not limited to, a dry vacuum sputter method combined with electroplating. In one or more embodiments, a dry vacuum sputter method combined with electroplating consists of multi-metal layers being sputtered in a high temperature evaporation system.

The UBM layer 122a, 122b, 122c may be patterned (e.g., by masking and etching) using any suitable technique known to one of skill in the art including, but not limited to, lithography, wet etching, or dry etching. The patterning of the UBM layer 122a, 122b, 122c provides anode pads in contact with the plated metal 120a, 120b, 120c.

Referring to FIG. 2, in one or more embodiments, the substrate may be removed after the LED array is integrated with the backplane driver and controller. This offers multiple advantages such as enhance light extraction and beam profiling. The standard approach for removing a sapphire substrate is by a laser lift-off process where a laser beam (UV laser, in the case of a sapphire substrate) is used to detach the substrate from the epitaxial layer. As illustrated in FIG. 2, three bottom contacts 120a, 120b, and 120c, are formed to independently drive each corresponding active region 106a, 106b, 106c. The die 100 of FIG. 2 aims at minimizing complexity of interconnect arrangement while maximizing the utilization of the epitaxial arca.

In one or more embodiments, the minimum number of electrodes (3 bottom contacts 120a, 120b, and 120c, and one lateral contact 120) requires an unconventional electronics driving scheme. Referring to FIG. 2, in one or more embodiments, a driving scheme 400 is mounted to the die 100. The driving scheme 400 includes a current source and three pulse width modulator (PWM) switches 404 per RGB pixel.

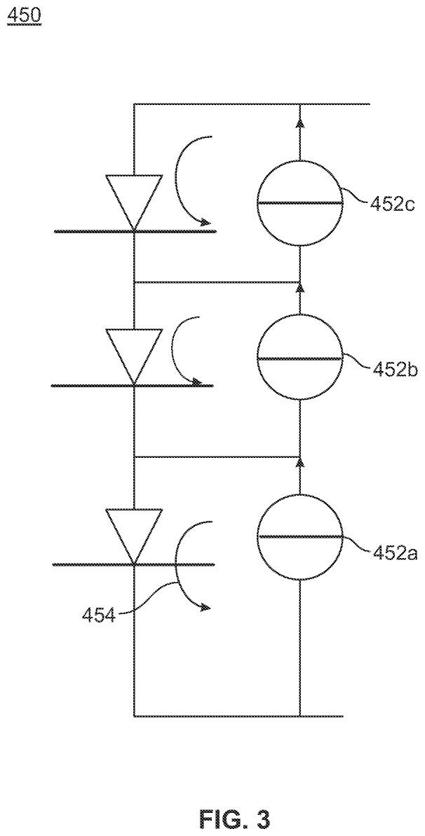

Referring to FIG. 3, in one or more embodiments, an alternative driving scheme 450. includes three independent current sources 452a, 452b, 452c connected in parallel to each active region, and three pulse width modulator (PWM) switches 454 per RGB pixel.

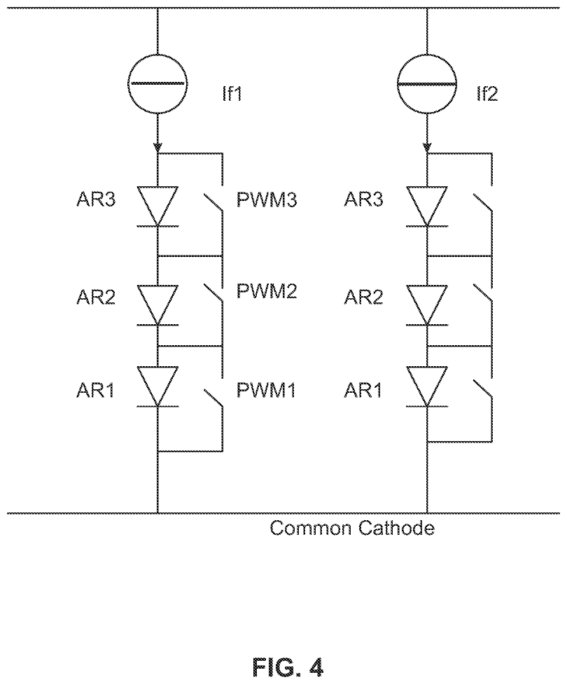

The driving scheme illustrated in FIG. 4 would typically be driven at constant voltage. The minimum compliance voltage for the current source to operate corresponds to a value higher than the sum of the forward voltage of the three active region. Since the applied (dc) voltage is constant, power dissipation in the current source will increase with the activation of the bypass switches PWM1-PWM3. The driving architecture illustrated in FIG. 4 has a common cathode including a single current source per individual RGB pixel and three independent active switches operating in PWM mode. Note that, while current is equal to all three active regions, the current density may not be so and can be designed for optimum operation.

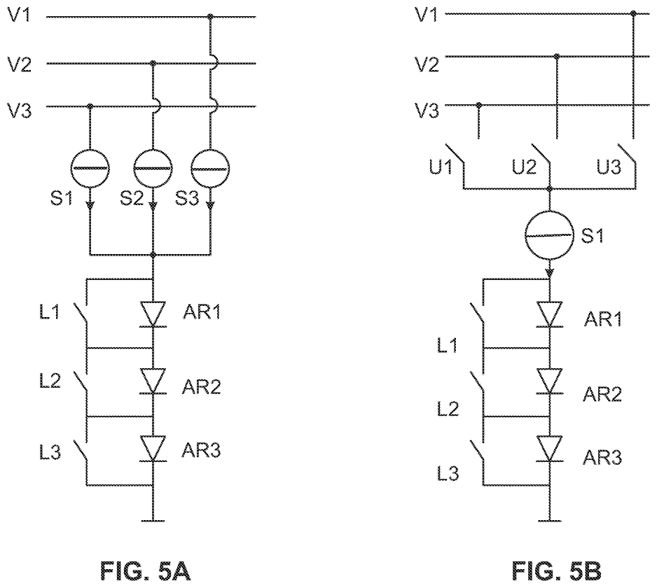

Driver schemes from FIGS. 5A and 5B reduce this problem by requiring two additional voltage source levels set up to be corresponding to the three different situations. First, all bypass switches are off. Second, only one bypass switch is on, and third, two bypass switches are on. In one or more embodiments, typical voltage levels could be 10V, 7.5V, and 4V. In FIG. 5A, only one of the three current sources (S1-S3) is active. The active current source corresponds to the one with the lowest possible compliant voltage, which varies depending upon the switch positions of L1, L2, and L3 as well as voltage levels V1, V2, and V3. In FIG. 5B, only a current source is employed. The position of upper and lower switches U1-U3 and L1-L3 are synchronized such that the minimum possible compliance voltage is applied across the current source for any light up configuration.

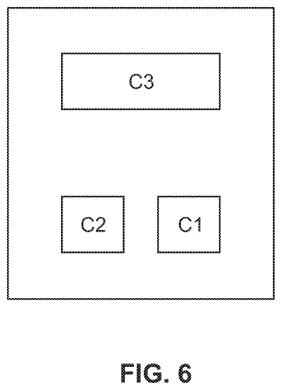

In one or more embodiments, the design of the die and driver schemes can be set up for optimal operation of the epitaxial layers. That is, for a given internal quantum efficiency (IQE) response as a function of current density, both contact areas and active region growth sequence can be selected such that peak IQE operation is reached in each active region at a common drive current. This is depicted in the example of FIG. 6, where contacts C1, C2, and C3 are chosen to further maximize epi area utilization Visualization systems, such as virtual reality systems and augmented reality systems, are becoming increasingly more common in fields such as entertainment, education, medicine, and business.

In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

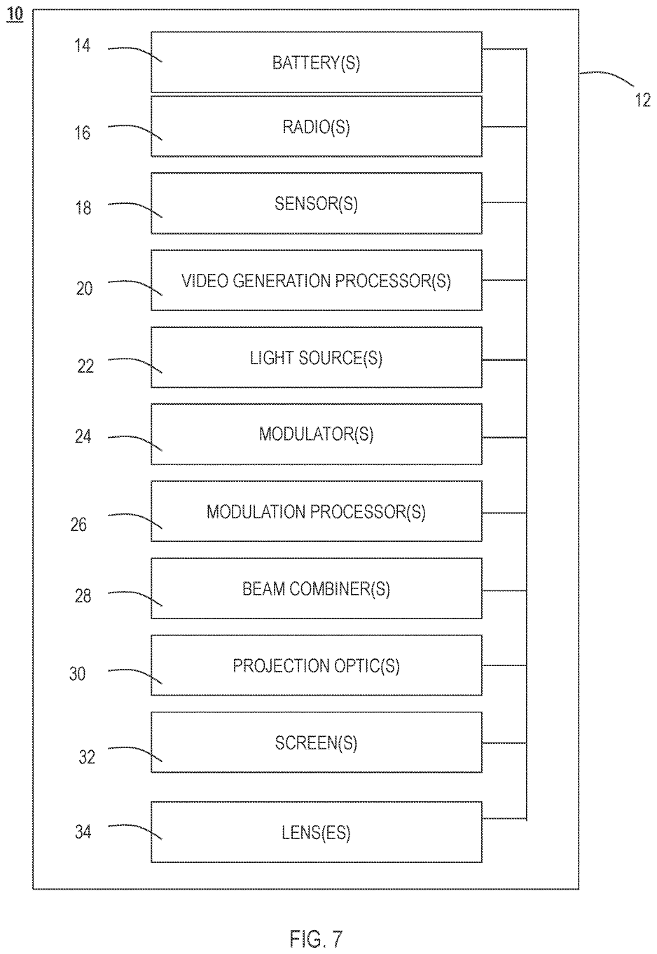

FIG. 7 shows a block diagram of an example of a visualization system 10 that utilizes the μLED array of one or more embodiments. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and bas light-emitting diode elements that are individually addressable and controllable (and/or controllable in groups and/or subsets), an array of micro-light-emitting diodes (microLEDs), and others.

A light-emitting diode can be a white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

In one or more embodiments, the light source 22 includes a LED of one or more embodiments that emits red-green-and-blue light (RGB).

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red-light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

For some configurations of augmented reality systems, the visualization system 10 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

### Embodiments

Various embodiments are listed below. It will be understood that the embodiments listed below may be combined with all aspects and other embodiments in accordance with the scope of the invention.
Embodiment (a). A light emitting diode (LED) comprising: a microLED die comprising an RGB pixel; and a driving scheme comprising a current source and three PWM switches per RGB pixel.
Embodiment (b). The LED of embodiment (a), wherein the microLED die comprises: a first mesa defining a red pixel, the first mesa comprising semiconductor layers, three active regions, two tunnel junctions, a transparent conductive oxide layer, and a first plated metal; a second mesa adjacent the first mesa, the second mesa defining a green pixel and comprising semiconductor layers, two active regions, two tunnel junctions, and a second plated metal; a third mesa adjacent the second mesa, the third mesa defining a blue pixel and comprising semiconductor layers, one active region, one tunnel junction, and a third plated metal; and a n-contact extending along sidewalls of each of the first mesa, the second mesa, and the third mesa.
Embodiment (c). The LED of embodiment (a) to (b), wherein the three active regions of the first mesa comprise a blue active region, a green active region, and red active region.
Embodiment (d). The LED of embodiment (a) to (c), wherein the two active regions of the second mesa comprise a blue active region and a green active region.
Embodiment (e). The LED of embodiment (a) to (d), wherein the active region of the third mesa comprises a blue active region.
Embodiment (f). The LED of embodiment (a) to (e), wherein the first plated metal has a first thickness, the second plated metal has a second thickness, and the third plated metal has a third thickness.
Embodiment (g). The LED of embodiment (a) to (f), wherein the second thickness is greater than the first thickness.
Embodiment (h). The LED of embodiment (a) to (g), wherein the third thickness is greater than the second thickness.
Embodiment (i). The LED of embodiment (a) to (h), further comprising a first dielectric layer on a top surface of the first mesa and extending to the red active region.
Embodiment (l). The LED of embodiment (a) to (i), further comprising a second dielectric on a top surface of the second mesa and extending to the green active region.
Embodiment (k). The LED of embodiment (a) to (j), further comprising a third dielectric layer on a top surface of the third mesa and extending to the blue active region.
Embodiment (l). The LED of any one of embodiment (a) to (k), wherein the dielectric layer comprises a low refractive index material having a refractive index in a range of from about 1.2 to about 2.
Embodiment (m). The LED of embodiment (a) to (l), wherein the dielectric layer comprises one or more of silicon oxide (SiO₂) and silicon nitride (Si₃N₄).
Embodiment (n). The LED of embodiment (a) to (m), wherein the semiconductor layers comprise a III-nitride material.
Embodiment (o). The LED of embodiment (a) to (n), wherein the III-nitride material independently comprises one or more of aluminum, gallium, and indium.
Embodiment (p). The LED of embodiment (a) to (o), wherein the driving scheme comprises three independent current sources connected in parallel to each of the active regions.
Embodiment (q). The LED of embodiment (a) to (p), wherein the driving scheme comprises a single current source per individual RGB pixel and three independent active switches operating on PWM mode.
Embodiment (r). The LED of embodiment (a) to (q), wherein the driving scheme comprises three voltage sources and three current sources, wherein only one of the current sources is active.
Embodiment(s). The LED of embodiment (a) to (r), wherein the driving scheme comprises three voltage sources and one current source.
Embodiment (t). A method of manufacturing an LED device, the method comprising: depositing a plurality of semiconductor layers including an N-type layer, an active region, and a P-type layer on a substrate; etching a portion of the semiconductor layers to form trenches and a first mesa, a second mesa, and a third mesa, wherein: the first mesa defines a red pixel, the first mesa comprising semiconductor layers, three active regions, two tunnel junctions, a transparent conductive oxide layer, and a first plated metal plug; the second mesa adjacent the first mesa, the second mesa defines a green pixel and comprising semiconductor layers, two active regions, two tunnel junctions, and a second plated metal plug; the third mesa adjacent the second mesa, the third mesa defines a blue pixel and comprising semiconductor layers, one active region, one tunnel junction, and a third plated plug; depositing a first dielectric material in a portion of the trenches; depositing a plated metal layer in the trenches; and forming a driving scheme.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.
Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A light emitting diode (LED) comprising:
a microLED die comprising an RGB pixel; and
a driving scheme comprising a current source and three PWM switches per RGB pixel.

2. The LED of claim 1, wherein the microLED die comprises:
a first mesa defining a red pixel, the first mesa comprising semiconductor layers, three active regions, two tunnel junctions, a transparent conductive oxide layer, and a first plated metal;
a second mesa adjacent the first mesa, the second mesa defining a green pixel and comprising semiconductor layers, two active regions, two tunnel junctions, and a second plated metal;
a third mesa adjacent the second mesa, the third mesa defining a blue pixel and comprising semiconductor layers, one active region, one tunnel junction, and a third plated metal; and
a n-contact extending along sidewalls of each of the first mesa, the second mesa, and the third mesa.

3. The LED of claim 2, wherein the three active regions of the first mesa comprise a blue active region, a green active region, and red active region.

4. The LED of claim 2, wherein the two active regions of the second mesa comprise a blue active region and a green active region.

5. The LED of claim 2, wherein the active region of the third mesa comprises a blue active region.

6. The LED of claim 2, wherein the first plated metal has a first thickness, the second plated metal has a second thickness, and the third plated metal has a third thickness.

7. The LED of claim 6, wherein the second thickness is greater than the first thickness.

8. The LED of claim 7, wherein the third thickness is greater than the second thickness.

9. The LED of claim 3, further comprising a first dielectric layer on a top surface of the first mesa and extending to the red active region.

10. The LED of claim 9, further comprising a second dielectric on a top surface of the second mesa and extending to the green active region.

11. The LED of claim 10, further comprising a third dielectric layer on a top surface of the third mesa and extending to the blue active region.

12. The LED of claim 11, wherein the first dielectric layer, the second dielectric layer, and the third dielectric layer independently comprise a low refractive index material having a refractive index in a range of from about 1.2 to about 2.

13. The LED of claim 12, wherein the first dielectric layer, the second dielectric layer, and the third dielectric layer independently comprise one or more of silicon oxide (SiO₂) and silicon nitride (Si₃N₄).

14. The LED of claim 2, wherein the semiconductor layers comprise a III-nitride material.

15. The LED of claim 2, wherein the III-nitride material independently comprises one or more of aluminum, gallium, and indium.

16. The LED of claim 2, wherein the driving scheme comprises three independent current sources connected in parallel to each of the active regions.

17. The LED of claim 2, wherein the driving scheme comprises a single current source per individual RGB pixel and three independent active switches operating on PWM mode.

18. The LED of claim 2, wherein the driving scheme comprises three voltage sources and three current sources, wherein only one of the current sources is active.

19. The LED of claim 2, wherein the driving scheme comprises three voltage sources and one current source.

20. A method of manufacturing the light emitting diode (LED) device of claim 2, the method comprising:
depositing the plurality of semiconductor layers including the N-type layer, the active region, and the P-type layer on substrate;
etching a portion of the semiconductor layers to form the trenches and the first mesa, the second mesa, and the third mesa, wherein:
the first mesa defines the red pixel, the first mesa comprising semiconductor layers, three active regions, two tunnel junctions, the transparent conductive oxide layer, and the first plated metal plug;
the second mesa adjacent the first mesa, the second mesa defines the green pixel and comprising semiconductor layers, two active regions, two tunnel junctions, and the second plated metal plug;
the third mesa adjacent the second mesa, the third mesa defines the blue pixel and comprising semiconductor layers, one active region, one tunnel junction, and the third plated plug;
depositing the first dielectric material in a portion of the trenches;
depositing the plated metal layer in the trenches; and
forming the driving scheme.
